(19) United States
(12) Patent Application Publication
(10) Pub. No.: US 2022/0108764 A1
(43) Pub. Date: Apr. 7, 2022

(54) ADDRESS GENERATION FOR ADAPTIVE DOUBLE DEVICE DATA CORRECTION SPARING

(71) Applicant: Intel Corporation, Santa Clara, CA (US)

(72) Inventors: Jing LING, Milpitas, CA (US); Sreenivas MANDAVA, Los Altos, CA (US)

(21) Appl. No.: 17/551,499

(22) Filed: Dec. 15, 2021

(51) Int. Cl. G11C 29/00; G11C 29/44; G11C 29/18

(52) U.S. Cl. CPC G11C 29/765; G11C 29/18; G11C 29/4401; G11C 29/883

(57) ABSTRACT

Adaptive Double Device Data Correction sparing uses memory addresses in increasing order. The last sparing address is stored as a memory address. Each system address for a processor memory transaction is converted to a memory address. The memory address is compared with the last sparing address to determine the Error Code Correction format for the processor memory transaction.

### FIELD

This disclosure relates to memory management and in particular to memory error management.

### BACKGROUND

Sparing techniques are employed to survive hard Dynamic Random Access Memory (DRAM) failures or hard errors. A hard error refers to an error with a physical device which prevents it from reading and/or writing correctly, and is distinguished from transient errors which are intermittent failures. Techniques are known for Single Device Data Correction (SDDC), Double Device Data Correction (DDDC) and Adaptive Double Device Data Correction (ADDDC) that provide error checking and correction (ECC) to protect against memory failure due to hard failures in DRAM.

SDDC checks and corrects single-bit or multiple-bit memory faults that affect an entire single DRAM device. DDDC provides error checking and correction to protect against memory failures in two, sequential, DRAM devices. ADDDC can be implemented at a rank or a bank granularity. A rank is a set of DRAM devices that are connected to the same chip select. A bank is an array of memory locations within a DRAM device.

Sparing operations copy the contents of memory to another location or another format. Examples of sparing operations include rank sparing, where data from a bad rank is copied to a spare rank, and device sparing where contents of a bad DRAM device are copied to another DRAM device.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 is a block diagram of a memory subsystem that includes a memory and a memory controller;

FIG. 2 is a block diagram of an embodiment of a system with a memory subsystem including at least one memory module coupled to a memory controller;

FIG. 3 illustrates cache lines stored in two regions in memory that operate in a non-lockstep configuration;

FIG. 4 illustrates cache lines stored in a failed memory region and a non-failed memory region in memory that operate in a lockstep configuration after completion of ADDDC sparing;

FIG. 5 illustrates an example of a sparing address for ADDDC mode using system addresses;

FIG. 6 is a method performed in the memory controller to perform spare copy; and

FIG. 7 is a block diagram of an embodiment of a computer system that includes the memory controller.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined as set forth in the accompanying claims.

### DESCRIPTION OF EMBODIMENTS

A spare copy operation copies data from one rank (a set of Dynamic Random Access Memory (DRAM) devices that are connected to the same chip select) to another rank when a spare rank is available, or copies data to the same location with a different Error Correction Code (ECC) format to obtain a spare device. The spare device can be used to store data from the failed DRAM device. Data may be split between the spare DRAM device and another non-failed DRAM device.

To perform the spare copy using the Adaptive Double Device Data Correction (ADDDC) format, the first half of a cache line is written in the original location (failed location in the failed DRAM device), and the second half of the cache line is written to a non-failed location (non-failed location in the non-failed DRAM device). Similarly, the original cache line in the non-failed location is stored in both the failed location and the non-failed location. Thus, data needs to be read from both failed and non-failed locations and then written back to avoid losing the data. The failed location and the non-failed location have different system addresses that are typically non-consecutive system addresses.

Processor memory transactions are performed while the spare copy is being performed. Each memory address for a processor memory transaction is compared with the last spare copy memory address. If the memory address for the processor memory transaction is less than or equal to the last spare copy memory address, the new error correction code format is used. If not, the old error correction code format is used.

For ADDDC sparing, there are two system addresses that need to be copied for each failing system address or location on the failed memory device. For rank based ADDDC sparing, the two system addresses have a common bank/row/column. For bank based ADDDC sparing, the two system addresses have common row/column. Each memory address for a processor memory transaction is compared with the last spare copy memory address using bank/row/column and there is a need to keep the order the same in both formats. This is further complicated when bank/row/column comes from different system address bits in different decoding modes, when address Exclusive OR (XOR) is applied and/or when decoding is performed using modulo operation.

In addition, the system address is logged when an ECC error is detected on sparing read and memory address regions (for example, one level memory, two level memory) specified in the system address can support different ECC formats.

ADDDC can be implemented at a rank or a bank granularity. Instead of using system addresses, ADDDC sparing uses memory addresses (bank/row/column (for ADDDC implemented at a rank granularity) or row/column (for ADDDC implemented at a bank granularity) address) in increasing order. The last sparing address is stored as a memory address. Each system address for a processor memory transaction is converted to a processor memory address. The processor memory address is compared with the last sparing address to determine the ECC format for the processor memory address using only the fields that are common between failed and non-failed addresses. Reverse address translation is implemented to convert the processor memory address back into a system address for error logging and to determine attributes that are available in the system address.

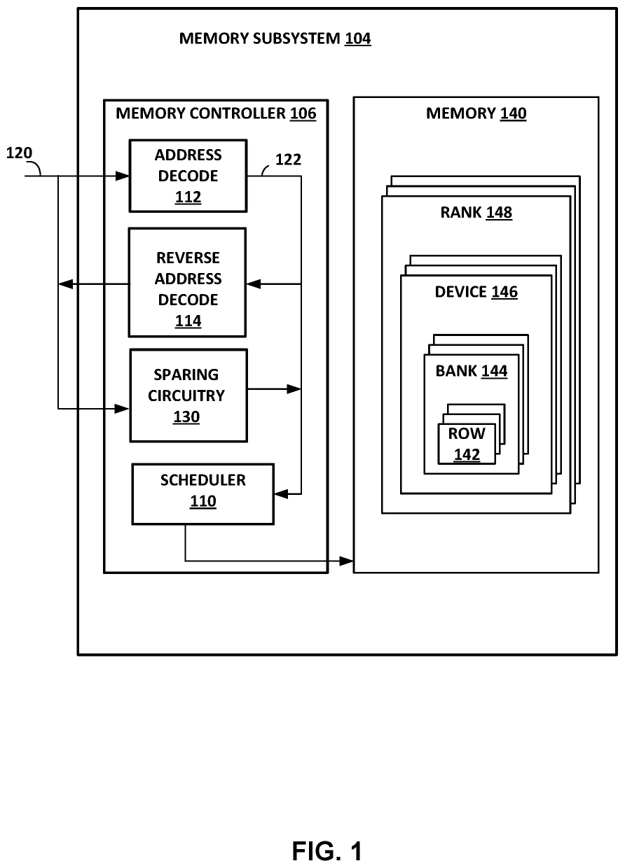

FIG. 1 is a block diagram of a memory subsystem 104 that includes a memory 140 and a memory controller 106.

The memory HO is a volatile memory. Volatile memory is memory whose state (and therefore the data stored on it) is indeterminate if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (double data rate version 3, original release by JEDEC (Joint Electronic Device Engineering Council) on Jun. 27, 2007, currently on release 21), DDR4 (DDR version 4, JESD79-4 initial specification published in September 2012 by JEDEC), DDR4E (DDR version 4, extended, currently in discussion by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5, originally published by JEDEC in January 2020, HBM2 (HBM version 2), originally published by JEDEC in January 2020, or others or combinations of memory technologies, and technologies based on derivatives or extensions of such specifications. The JEDEC standards are available at www.jedec.org.

The memory 140 includes one or more devices 146. In an embodiment, the memory device 146 is a DRAM device. The memory address 122 can include a rank address, a bank address, a row address and a column to identify a row 142 and a column in a bank 144 in a device 146 in a rank 148 in the memory 140.

Address decode circuitry 112 in the memory controller 106 converts a received system address 120 to a memory address 122. The memory address 122 can include bits to identify a DIMM and rank in the memory 140. The system address 120 can be used to access all locations in the memory 140 or just locations for one channel (channel address) in the memory 140.

Sparing operations are performed by sparing circuitry 130. Sparing operations copy the contents of memory to another location or format. Examples of sparing operations are rank sparing, where data from a bad rank is copied to a spare rank, and device sparing where contents of a bad DRAM device are copied to another DRAM device. Sparing circuitry 130 generates memory address 122. Reverse address decode circuitry 114 converts the memory address 122 to a converted system address that is used for error logging and sparing operations.

The memory 140 can be a 3D Stacked (3DS) DIMM with sub-ranks that do not have a physical chip select. In one embodiment, sub-rank is grouped with bank. During rank ADDDC, failed and non-failed addresses have the same sub-rank value. In another embodiment, sub-rank is grouped with rank during rank ADDDC.

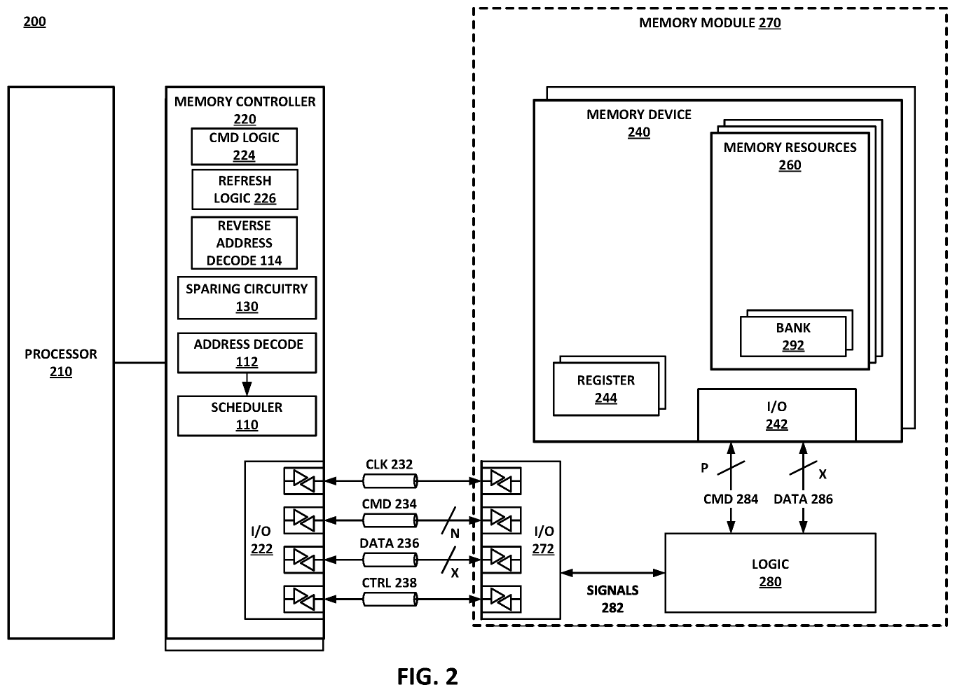

FIG. 2 is a block diagram of an embodiment of a system 200 with a memory subsystem including at least one memory module 270 coupled to a memory controller 220. The memory controller 220 includes address decode circuitry 112, reverse address decode circuitry 114, sparing circuitry 130 and scheduler 110 discussed in conjunction with FIG. 1. System 200 includes a processor 210 and elements of a memory subsystem in a computing device. Processor 210 represents a processing unit of a computing platform that can execute an operating system (OS) and applications, which can collectively be referred to as the host or user of the memory. The OS and applications execute operations that result in memory accesses. Processor 210 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or storage controller. Such devices can be integrated with the processor in some systems (for example, in a System-on-Chip (SoC)) or attached to the processer via a bus (e.g., Peripheral Component Interconnect express (PCIe)), or a combination.

Reference to memory devices can apply to volatile memory technologies or nonvolatile memory technologies. Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 220 represents one or more memory controller circuits or devices for system 200. Memory controller 220 represents control logic that generates memory access commands in response to the execution of operations by processor 210. Memory controller 220 accesses one or more memory devices 240. Memory devices 240 can be DRAM devices in accordance with any referred to above. Memory controller 220 includes I/O interface logic 222 to couple to a memory bus. I/O interface logic 222 (as well as I/O interface logic 242 of memory device 240) can include pins, pads, connectors, signal lines, traces, or wires, or other hardware to connect the devices, or a combination of these. I/O interface logic 222 can include a hardware interface. As illustrated, I/O interface logic 222 includes at least drivers/transceivers for signal lines. Commonly, wires within an integrated circuit interface couple with a pad, pin, or connector to interface signal lines or traces or other wires between devices. I/O interface logic 222 can include drivers, receivers, transceivers, or termination, or other circuitry or combinations of circuitry to exchange signals on the signal lines between the devices.

The exchange of signals includes at least one of transmit or receive. While shown as coupling I/O interface logic 222 from memory controller 220 to I/O interface logic 242 of memory device 240, it will be understood that in an implementation of system 200 where groups of memory devices 240 are accessed in parallel, multiple memory devices can include I/O interfaces to the same interface of memory controller 220. In an implementation of system 200 including one or more memory modules 270, I/O interface logic 242 can include interface hardware of the memory module in addition to interface hardware on the memory device itself. Other memory controllers 220 can include separate interfaces to other memory devices 240.

The bus between memory controller 220 and memory devices 240 can be a double data rate (DDR) high-speed DRAM interface to transfer data that is implemented as multiple signal lines coupling memory controller 220 to memory devices 240. The bus may typically include at least clock (CLK) 232, command/address (CMD) 234, and data (write data (DQ) and read data (DQO) 236, and zero or more control signal lines 238. In one embodiment, a bus or connection between memory controller 220 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for data (write DQ and read DQ) can be referred to as a “data bus.” It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 220 and memory devices 240. An example of a serial bus technology is 8B10B encoding and transmission of high-speed data with embedded clock over a single differential pair of signals in each direction.

In one embodiment, one or more of CLK 232, CMD 234, Data 236, or control 238 can be routed to memory devices 240 through logic 280. Logic 280 can be or include a register or buffer circuit. Logic 280 can reduce the loading on the interface to I/O interface 222, which allows faster signaling or reduced errors or both. The reduced loading can be because I/O interface 222 sees only the termination of one or more signals at logic 280, instead of termination of the signal lines at every one or memory devices 240 in parallel. While I/O interface logic 242 is not specifically illustrated to include drivers or transceivers, it will be understood that I/O interface logic 242 includes hardware necessary to couple to the signal lines. Additionally, for purposes of simplicity in illustrations, I/O interface logic 242 does not illustrate all signals corresponding to what is shown with respect to I/O interface 222. In one embodiment, all signals of I/O interface 222 have counterparts at I/O interface logic 242. Some or all of the signal lines interfacing I/O interface logic 242 can be provided from logic 280. In one embodiment, certain signals from I/O interface 222 do not directly couple to I/O interface logic 242, but couple through logic 280, while one or more other signals may directly couple to I/O interface logic 242 from I/O interface 222 via I/O interface 272, but without being buffered through logic 280. Signals 282 represent the signals that interface with memory devices 240 through logic 280.

It will be understood that in the example of system 200, the bus between memory controller 220 and memory devices 240 includes a subsidiary command bus CMD 234 and a subsidiary data bus 236. In one embodiment, the subsidiary data bus 236 can include bidirectional lines for read data and for write/command data. In another embodiment, the subsidiary data bus 236 can include unidirectional write signal lines for write and data from the host to memory, and can include unidirectional lines for read data from the memory device 240 to the host. In accordance with the chosen memory technology and system design, control signals 238 may accompany a bus or sub bus, such as strobe lines DQS. Based on design of system 200, or implementation if a design supports multiple implementations, the data bus can have more or less bandwidth per memory device 240. For example, the data bus can support memory devices 240 that have either a x32 interface, a x16 interface, a x8 interface, or another interface. The convention “xW,” where W is an integer that refers to an interface size or width of the interface of memory device 240, which represents a number of signal lines to exchange data with memory controller 220. The number is often binary, but is not so limited. The interface size of the memory devices is a controlling factor on how many memory devices can be used concurrently in system 200 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

Memory devices 240 represent memory resources for system 200. In one embodiment, each memory device 240 is a separate memory die. Each memory device 240 includes I/O interface logic 242, which has a bandwidth determined by the implementation of the device (e.g., x16 or x8 or some other interface bandwidth). I/O interface logic 242 enables each memory device 240 to interface with memory controller 220. I/O interface logic 242 can include a hardware interface, and can be in accordance with I/O interface logic 222 of memory controller 220, but at the memory device end. In one embodiment, multiple memory devices 240 are connected in parallel to the same command and data buses. In another embodiment, multiple memory devices 240 are connected in parallel to the same command bus, and are connected to different data buses. For example, system 200 can be configured with multiple memory devices 240 coupled in parallel, with each memory device responding to a command, and accessing memory resources 260 internal to each. For a write operation, an individual memory device 240 can write a portion of the overall data word, and for a read operation, an individual memory device 240 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word are provided or received by other memory devices in parallel.

In one embodiment, memory devices 240 can be organized into memory modules 270. In one embodiment, memory modules 270 represent dual inline memory modules (DIMMs). Memory modules 270 can include multiple memory devices 240, and the memory modules can include support for multiple separate channels to the included memory devices disposed on them.

Memory devices 240 each include memory resources 260. Memory resources 260 represent individual arrays of memory locations or storage locations for data. Typically, memory resources 260 are managed as rows of data, accessed via word line (rows) and bit line (individual bits within a row) control. Memory resources 260 can be organized as separate banks of memory. Banks may refer to arrays of memory locations within a memory device 240. In one embodiment, banks of memory are divided into sub-banks with at least a portion of shared circuitry (e.g., drivers, signal lines, control logic) for the sub-banks.

In one embodiment, memory devices 240 include one or more registers 244. Register 244 represents one or more storage devices or storage locations that provide configuration or settings for the operation of the memory device. In one embodiment, register 244 can provide a storage location for memory device 240 to store data for access by memory controller 220 as part of a control or management operation. In one embodiment, register 244 includes one or more Mode Registers. In one embodiment, register 244 includes one or more multipurpose registers. The configuration of locations within register 244 can configure memory device 240 to operate in different “mode,” where command information can trigger different operations within memory device 240 based on the mode. Additionally, or in the alternative, different modes can also trigger different operation from address information or other signal lines depending on the mode. Settings of register 244 can indicate configuration for I/O settings (e.g., timing, termination, driver configuration, or other I/O settings).

Memory controller 220 includes scheduler 110, which represents logic or circuitry to generate and order transactions to send to memory device 240. From one perspective, the primary function of memory controller 220 is to schedule memory access and other transactions to memory device 240. Such scheduling can include generating the transactions themselves to implement the requests for data by processor 210 and to maintain integrity of the data (e.g., such as with commands related to refresh).

Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 220 typically includes logic to allow selection and ordering of transactions to improve performance of system 200. Thus, memory controller 220 can select which of the outstanding transactions should be sent to memory device 240 in which order, which is typically achieved with logic much more complex than a simple first-in first-out algorithm. Memory controller 220 manages the transmission of the transactions to memory device 240, and manages the timing associated with the transaction. In one embodiment, transactions have deterministic timing, which can be managed by memory controller 220 and used in determining how to schedule the transactions.

Referring again to memory controller 220, memory controller 220 includes command (CMD) logic 224, which represents logic or circuitry to generate commands to send to memory devices 240. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 240, memory controller 220 can issue commands via I/O 222 to cause memory device 240 to execute the commands. Memory controller 220 can implement compliance with standards or specifications by access scheduling and control.

Referring again to logic 280, in one embodiment, logic 280 buffers certain signals 282 from the host to memory devices 240. In one embodiment, logic 280 buffers data signal lines 236 as data 286, and buffers command (or command and address) lines of CMD 234 as CMD 284. In one embodiment, data 286 is buffered, but includes the same number of signal lines as data 236. Thus, both are illustrated as having X signal lines. In contrast, CMD 234 has fewer signal lines than CMD 284. Thus, P>N. The N signal lines of CMD 234 are operated at a data rate that is higher than the P signal lines of CMD 284. For example, P can equal 2N, and CMD 284 can be operated at a data rate of half the data rate of CMD 234.

In one embodiment, memory controller 220 includes refresh logic 226. Refresh logic 226 can be used for memory resources 260 that are volatile and need to be refreshed to retain a deterministic state. In one embodiment, refresh logic 226 indicates a location for refresh, and a type of refresh to perform. Refresh logic 226 can execute external refreshes by sending refresh commands. For example, in one embodiment, system 200 supports all bank refreshes as well as per bank refreshes. All bank refreshes cause the refreshing of a selected bank 292 within all memory devices 240 coupled in parallel. Per bank refreshes cause the refreshing of a specified bank 292 within a specified memory device 240.

System 200 can include a memory circuit, which can be or include logic 280. To the extent that the circuit is considered to be logic 280, it can refer to a circuit or component (such as one or more discrete elements, or one or more elements of a logic chip package) that buffers the command bus. To the extent the circuit is considered to include logic 280, the circuit can include the pins of packaging of the one or more components, and may include the signal lines. The memory circuit includes an interface to the N signal lines of CMD 234, which are to be operated at a first data rate. The N signal lines of CMD 234 are host-facing with respect to logic 280. The memory circuit can also include an interface to the P signal lines of CMD 284, which are to be operated at a second data rate lower than the first data rate. The P signal lines of CMD 284 are memory-facing with respect to logic 280. Logic 280 can either be considered to be the control logic that receives the command signals and provides them to the memory devices, or can include control logic within it (e.g., its processing elements or logic core) that receive the command signals and provide them to the memory devices.

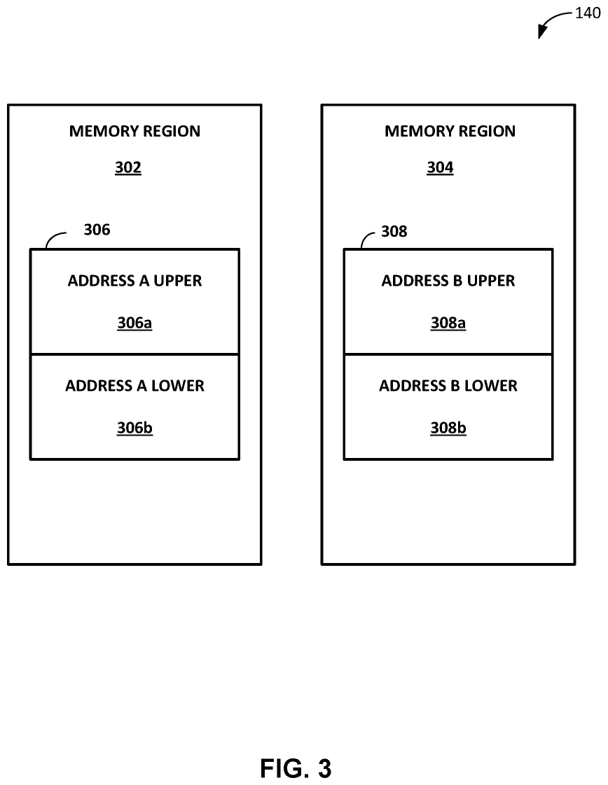

FIG. 3 illustrates cache lines stored in two regions 302, 304 in memory 140 that operate in a non-lockstep configuration. The regions can be memory ranks 148 or memory banks 144. The Error Correction Code (ECC) format used in the non-lockstep configuration is Single Data Device Correction (SDDC).

Each cache line stored in the memory 140 includes an upper half and a lower half. Cache line 306 at Address A in region 302 includes Address A upper half 306a and Address A lower half 306b. Cache line 308 at Address B in region 304 includes Address B upper half 308a and Address B lower half 308b. In an embodiment, a cache line 306, 308 has 64 bytes, with the respective upper half 306a, 308a and lower half 306b, 308b of the cache line 306, 308 each having 32 bytes.

After a failure is detected in a memory region 302, 304, the failed memory region is paired with a non-failed memory region. The failed memory region and non-failed memory region are the same size. The ECC (Error Correction Code) format is changed from SDDC to ADDDC as cache lines in the failed memory region or in the non-failed memory region are copied to both the failed memory region and the non-failed memory region in virtual lock step (VLS) mode.

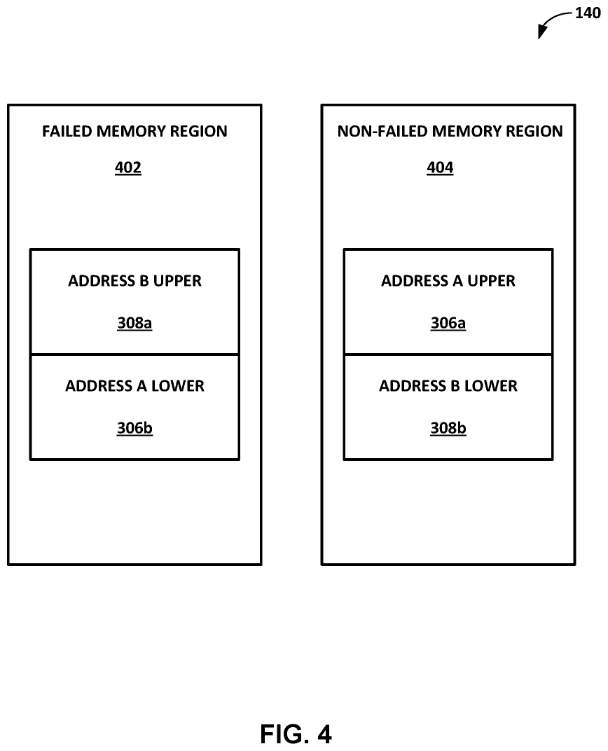

FIG. 4 illustrates cache lines stored in a failed memory region 402 and a non-failed memory region 404 in memory 140 that operate in a lockstep configuration after completion of ADDDC sparing. The failed memory region 402 is paired with the non-failed memory region 404. A cache line in the failed memory region 402 or in the non-failed memory region 404 is copied by sparing circuitry 130 in the memory controller 106 to both the failed memory region 402 and non-failed memory region 404 in virtual lockstep format. Address A lower half 306b and Address B lower half 308b are referred to as “primary” and are not copied. Address A upper half 306a and Address B upper half 308a are referred to as “buddy” and are copied. That is, Address A upper half 306a is copied to the non-failed memory region 404 and Address B upper half 308a is copied to the failed memory region 402.

To perform the data transfers between the failed memory region 402 and a non-failed memory region 404, the sparing circuitry 130 walks through every memory address in the failed region 402. The data from the failed address (Address A lower half 306b and Address A upper half 306a) in the failed memory region 402 and data from the associated address (Address B lower half 308b and Address B upper half 308a) in the non-failed memory region 404 are read and stored in the memory controller 106.

The sparing circuitry 130 writes Address A lower half 306b and Address B upper half 308a to failed region 402 and writes Address A upper half 306a and Address B lower half 308b to non-failed region 404. This process can be referred to as a spare copy. The spare copy can be periodically paused to allow other memory access requests (for example, CPU memory access requests) to be performed in memory 140.

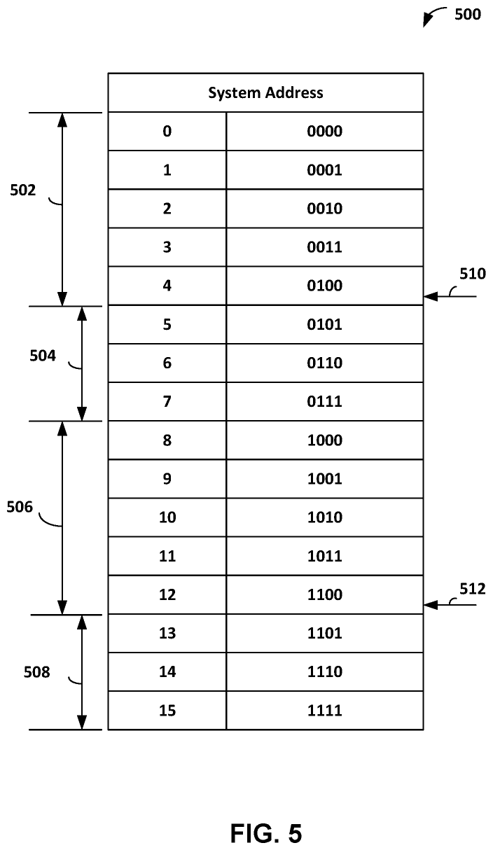

FIG. 5 illustrates an example of a sparing address for ADDDC mode using system addresses. In the example shown, the sparing circuitry 130 (also referred to as a sparing engine) walks through system addresses 0-15 (binary 0000-1111) 500. The sparing has completed the spare copy for addresses 502 (system addresses 0-4 and for addresses 506 (system addresses 8-12). Addresses 502 and addresses 504 use ADDDC format for ECC. Addresses 504 and 508 use SDDC format for ECC. The last failed region spare system address 510 is 4 and the last non-failed region spare system address 512 is 12. For rank based ADDDC sparing, the two system addresses have a common bank/row/column. For bank based ADDDC sparing, the two system addresses have a common row/column. In the example shown in FIG. 5, for rank based sparing, the Most Significant bit of the system address corresponds to the rank (rank 0 or rank 1) in the corresponding memory address, and the other three bits correspond to the bank/row/column in the corresponding memory address.

Returning to FIG. 1, address decode 112 in memory controller 106 converts system addresses 120 to memory addresses 122. The memory addresses 122 are in bank/row/column format. ADDDC sparing to use memory addresses in increasing order. The memory addresses include bank/row/column (for ADDDC implemented at a rank granularity) or row/column (for ADDDC implemented at a bank granularity) address). The sparing circuitry 130 in the memory controller 106 operates on the memory addresses 122 and increments the memory addresses 122 to perform the sparing operation. The last sparing address is stored as a memory address (a last sparing memory address). Each system address 120 for a processor memory transaction is converted to a processor memory address in address decode 112. The processor memory address is compared with the last spare copy memory address to determine the ECC format (ADDDC or SDDC) for the processor memory address using only the bits that are common between failed and non-failed addresses. For rank based ADDDC sparing, the two system addresses have a common bank/row/column (the memory address includes a row address, a column address and a bank address). For bank based ADDDC sparing, the two system addresses have a common row/column (the memory address includes a row address and a column address). If the processor memory address is less than or equal to the last spare copy memory address, ADDDC format is used. Otherwise, SDDC format is used.

Reverse address translation is implemented in reverse address decode 114 to convert the processor memory address back to a system address for error logging in error circuitry 130 and to determine attributes that are available in the system address. An attribute in the system address can indicate whether the system address is for a one-level memory or for near memory of a two-level memory.

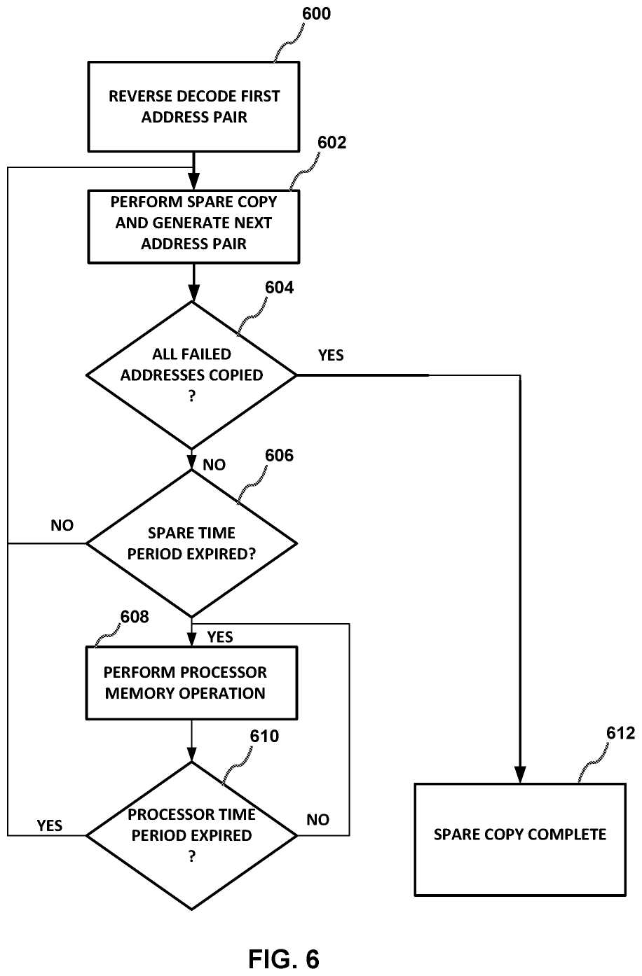

FIG. 6 is a method performed in the memory controller 106 to perform spare copy.

At block 600, the first address pair for sparing are reversed translated from memory address 122 to system address 120 by the sparing circuitry 130 in the memory controller 106.

At block 602, spare copy of the current sparing address pair is performed. Reverse address translation can take multiple cycles (for example, to handle division by non-power-of-2 value, for example division by 3). Reverse address translation for the next sparing address pair is performed while the sparing copy of the current address pair is on-going to hide the reverse translation time.

At block 604, if all failed address have been copied, processing continues with block 612. If not, processing continues with block 606.

At block 606, if the spare time period to perform sparing operations (also referred to as a spare window) has expired, processing continues with block 608. If not, processing continues with block 602 to perform spare copy of the next sparing address pair.

At block 608, processor memory operations are unblocked. The processor memory address is compared with the last sparing address pair to determine the ECC format to use.

At block 610, if the processor time period to perform processor memory operations (also referred to as a CPU transaction window) has expired, processing continues with block 602 to perform the next sparing operation. If not, processing continues with block 608 to perform the next processor memory operation.

At block 612, the spare copy is complete.

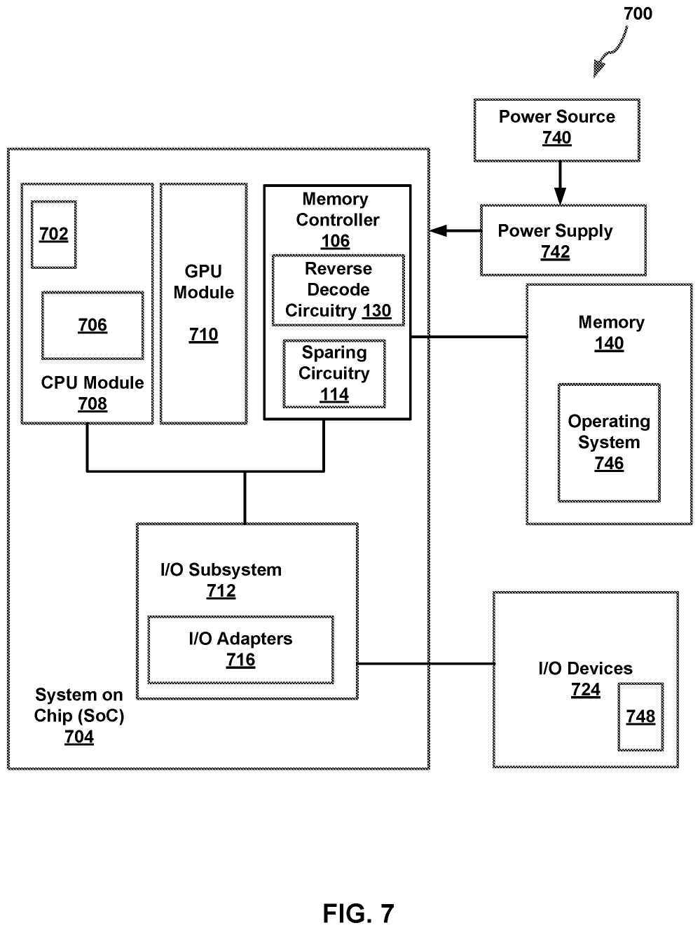

FIG. 7 is a block diagram of an embodiment of a computer system 700 that includes the memory controller 106. Computer system 700 can correspond to a computing device including, but not limited to, a server, a workstation computer, a desktop computer, a laptop computer, and/or a tablet computer.

The computer system 700 includes a system on chip (SOC or SoC) 704 which combines processor, graphics, memory, and Input/Output (I/O) control logic into one SoC package. The SoC 704 includes at least one Central Processing Unit (CPU) module 708, memory controller 106, and a Graphics Processor Unit (GPU) 710. In other embodiments, the memory controller 106 can be external to the SoC 704. The CPU module 708 includes at least one processor core 702 and a level 2 (L2) cache 706. The memory controller 106 is communicatively coupled to memory 140. The memory controller 106 includes the reverse address decode circuitry 114 and sparing circuitry 130 discussed in conjunction with FIG. 1.

Although not shown, each of the processor core(s) 702 can internally include one or more instruction/data caches, execution units, prefetch buffers, instruction queues, branch address calculation units, instruction decoders, floating point units, retirement units, etc. The CPU module 708 can correspond to a single core or a multi-core general purpose processor, such as those provided by Intel® Corporation, according to one embodiment.

The Graphics Processor Unit (GPU) 710 can include one or more GPU cores and a GPU cache which can store graphics related data for the GPU core. The GPU core can internally include one or more execution units and one or more instruction and data caches. Additionally, the Graphics Processor Unit (GPU) 710 can contain other graphics logic units that are not shown in FIG. 7, such as one or more vertex processing units, rasterization units, media processing units, and codecs.

Within the I/O subsystem 712, one or more I/O adapter(s) 716 are present to translate a host communication protocol utilized within the processor core(s) 702 to a protocol compatible with particular I/O devices. Some of the protocols that adapters can be utilized for translation include Peripheral Component Interconnect (PCI)-Express (PCIe); Universal Serial Bus (USB); Serial Advanced Technology Attachment (SATA) and Institute of Electrical and Electronics Engineers (IEEE) 1594 “Firewire”.

The I/O adapter(s) 716 can communicate with external I/O devices 724 which can include, for example, user interface device(s) including a display and/or a touch-screen display 748, printer, keypad, keyboard, communication logic, wired and/or wireless, storage device(s) including hard disk drives (“HDD”), solid-state drives (“SSD”), removable storage media, Digital Video Disk (DVD) drive, Compact Disk (CD) drive, Redundant Array of Independent Disks (RAID), tape drive or other storage device. The storage devices can be communicatively and/or physically coupled together through one or more buses using one or more of a variety of protocols including, but not limited to, SAS (Serial Attached SCSI (Small Computer System Interface)), PCIe (Peripheral Component Interconnect Express), NVMe (NVM Express) over PCIe (Peripheral Component Interconnect Express), and SATA (Serial ATA (Advanced Technology Attachment)).

Additionally, there can be one or more wireless protocol I/O adapters. Examples of wireless protocols, among others, are used in personal area networks, such as IEEE 802.15 and Bluetooth, 4.0; wireless local area networks, such as IEEE 802.11-based wireless protocols; and cellular protocols.

Memory 140 can store an operating system 746. The operating system 746 is software that manages computer hardware and software including memory allocation and access to I/O devices. Examples of operating systems include Microsoft® Windows®, Linux®, iOS® and Android®.

Power source 740 provides power to the components of system 700. More specifically, power source 740 typically interfaces to one or multiple power supplies 742 in system 700 to provide power to the components of system 700. In one example, power supply 742 includes an AC to DC (alternating current to direct current) adapter to plug into a wall outlet. Such AC power can be renewable energy (e.g., solar power) power source 740. In one example, power source 740 includes a DC power source, such as an external AC to DC converter. In one example, power source 740 or power supply 742 includes wireless charging hardware to charge via proximity to a charging field. In one example, power source 740 can include an internal battery or fuel cell source.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope.

Therefore, the illustrations and examples herein should be construed in an illustrative, and not a restrictive sense. The scope of the invention should be measured solely by reference to the claims that follow.

What is claimed is:

1. A memory controller comprising:
a sparing circuitry to store a last sparing address as a memory address for a memory, to convert a system address for a processor memory transaction to a processor memory address and to compare the processor memory address with the last sparing address to determine an Error Correction Code format for the processor memory address; and
reverse address decode circuitry to receive the processor memory address from the sparing circuitry and to convert the processor memory address to a second system address for error logging.

2. The memory controller of claim 1, wherein the Error Correction Code format is Adaptive Double Device Data Correction (ADDDC) or Single Device Data Correction (SDDC).

3. The memory controller of claim 1, wherein the Error Correction Code format is Adaptive Double Device Data Correction (ADDDC) and the sparing circuitry to use memory addresses in increasing order.

4. The memory controller of claim 3, wherein the sparing circuitry performs rank based ADDDC sparing.

5. The memory controller of claim 3, wherein the sparing circuitry performs bank based ADDDC sparing.

6. The memory controller of claim 5, wherein the memory is a Dynamic Random Access Memory.

7. The memory controller of claim 6, wherein the memory address includes a row address, a column address and a bank address.

8. A method performed by a memory controller comprising:
storing, in a sparing circuitry, a last sparing address as a memory address for a memory;
converting, in the sparing circuitry, a system address for a processor memory transaction to a processor memory address;
comparing, in the sparing circuitry, the processor memory address with the last sparing address to determine an Error Correction Code format for the processor memory address; and
converting, in reverse address decode circuitry, the processor memory address to a second system address for error logging.

9. The method of claim 8, wherein the Error Correction Code format is Adaptive Double Device Data Correction (ADDDC) or Single Device Data Correction (SDDC).

10. The method of claim 8, wherein the Error Correction Code format is Adaptive Double Device Data Correction (ADDDC) and the sparing circuitry to use memory addresses in increasing order.

11. The method of claim 10, wherein the sparing circuitry performs rank based ADDDC sparing.

12. The method of claim 10, wherein the sparing circuitry performs bank based ADDDC sparing.

13. The method of claim 8, wherein the memory is a Dynamic Random Access Memory.

14. A system comprising:
a processor;
a memory; and
a memory controller communicatively coupled to the processor and the memory, the memory controller comprising:
a sparing circuitry to store a last sparing address as a memory address, to convert a system address for a processor memory transaction to a processor memory address and to compare the processor memory address with the last sparing address to determine an Error Correction Code format for the processor memory address; and
reverse address decode circuitry to receive the processor memory address from the sparing circuitry and to convert the processor memory address to a second system address for error logging.

15. The system of claim 14, wherein the Error Correction Code format is Adaptive Double Device Data Correction (ADDDC) or Single Device Data Correction (SDDC).

16. The system of claim 14, wherein the Error Correction Code format is Adaptive Double Device Data Correction (ADDDC) and the sparing circuitry to use memory addresses in increasing order.

17. The system of claim 16, wherein the sparing circuitry performs rank based ADDDC sparing.

18. The system of claim 16, wherein the sparing circuitry performs bank based ADDDC sparing.

19. The system of claim 14, wherein the memory is a Dynamic Random Access Memory.

20. The system of claim 14, further comprising one or more of:
a display communicatively coupled to the processor; or
a battery coupled to the processor.
